(19) United States
(12) Patent Application Publication
(10) Pub. No.: US 2023/0044166 A1
(43) Pub. Date: Feb. 9, 2023

(54) ACCELERATED TIME DOMAIN MAGNETIC RESONANCE SPIN TOMOGRAPHY

(71) Applicant: UMC Utrecht Holding B.V., Utrecht (NL)

(72) Inventors: Hongyan Liu, Utrecht (NL); Alessandro Sbrizzi, Utrecht (NL); Cornelis Antonius Theodorus Van Den Berg, Utrecht (NL)

(21) Appl. No.: 17/791,527

(22) PCT Filed: Jan. 8, 2021
(86) PCT No.: PCT/EP2021/050274

§ 371 Date: Jul. 7, 2022

(30) Foreign Application Priority Data
Jan. 8, 2020 (NL) 2024624

(51) Int. Cl. G01R 33/56; G01R 33/50

(52) U.S. Cl. CPC G01R 33/5608; G01R 33/50

(57) ABSTRACT

The present patent disclosure relates to a method and a device 700 for determining a spatial distribution of at least one tissue parameter within a sample on a time domain magnetic resonance, TDMR, signal emitted from the sample after excitation of the sample according to an applied pulse sequence, a method of obtaining at least one time dependent parameter relating to a magnetic resonance, MR, signal emitted from a sample after excitation of the sample according to an applied spin echo pulse sequence, and a computer program product for performing the methods. A TDMR signal model is used to approximate the emitted time domain magnetic resonance signal. The model is factorized into one or more first matrix operators that have a non-linear dependence on the at least one tissue parameter and a remainder of the TDMR signal model.

### CROSS-REFERENCE TO RELATED APPLICATIONS

The present application is a U.S. National Stage entry under 35 U.S.C. § 371 of International Application No. PCT/EP2021/050274 filed Jan. 8, 2021, which claims priority to and the benefit of Netherlands Application No. 2024624 filed Jan. 8, 2020, which applications are hereby incorporated by reference in their entirety.

### FIELD OF THE INVENTION

The present patent disclosure relates to a method and a device for determining a spatial distribution of at least one tissue parameter within a sample on a time domain magnetic resonance, TDMR, signal emitted from the sample after excitation of the sample according to an applied pulse sequence, a method of obtaining at least one time dependent parameter relating to a magnetic resonance, MR, signal emitted from a sample after excitation of the sample according to an applied sequence, and a computer program product for performing the methods.

### BACKGROUND

Magnetic resonance imaging (MRI) is an imaging modality used for many applications and with many sequence parameters that can be tuned and many imaging parameters that can be observed to extract e.g. different kinds of biological information. Conventional MRI image reconstruction involves acquiring a k-space signal and performing inverse fast Fourier transform (FFT) on the acquired data. Conventional MRI imaging is slow because for every parameter to be measured (e.g. T₁ or T₂) several separate MRI measurements are to be acquired with the MRI device having different settings. A scan can take as much as 30-45 minutes.

Magnetic resonance spin tomography in the time domain (MR-STAT) is a quantitative method to obtain MR images directly from time domain data. Particularly, MR-STAT is a framework for obtaining multi-parametric quantitative MR maps using data from single short scans.

In MR-STAT, the parameter maps are reconstructed by iteratively solving the large scale, non-linear problem

$$\hat{α} = arg {min}_{α} \frac{1}{2} {‖ d - s ( α ) ‖}_{2}^{2} , \qquad ( 1 )$$

where d is the data in time domain (i.e. previous to FFT), a denotes all parameter maps (e.g. for tissue parameters such as T₁, T₂, PD, etc.), and s is a volumetric signal model. This approach is described in WO 2016/184779 A1 and recent improvements have been obtained and are the subject of at present pending application NL2022890. However, MR-STAT reconstructions still lead to long computation times because of the large scale of the problem, requiring a high performance computing cluster for application in a clinical work-flow.

It is an object, among objects, of the present patent disclosure to improve the conversion of the time domain MR signal to the quantitative MR maps.

### SUMMARY

According to a first aspect, there is provided a method for determining a spatial distribution of at least one tissue parameter within a sample based on a measured time domain magnetic resonance, TDMR, signal emitted from the sample after excitation of the sample according to an applied pulse sequence, the method comprising:

i) determining a TDMR signal model to approximate the emitted time domain magnetic resonance signal, wherein the TDMR signal model is dependent on TDMR signal model parameters comprising the at least one tissue parameter within the sample,

wherein the model is factorized into one or more first matrix operators that have a non-linear dependence on the at least one tissue parameter and a remainder of the TDMR signal model;

ii) performing optimization with an objective function and constraints based on the first matrix operators and the remainder of the TDMR signal model until a difference between the TDMR signal model and the TDMR signal emitted from the sample is below a predefined threshold or until a predetermined number of repetitions is completed, in order to obtain an optimized or final set of TDMR signal model parameters; and

iii) providing or obtaining from the optimized or final set of TDMR signal model parameters the spatial distribution of the at least one tissue parameter.

Due to the factorizing of the model into the one or more first matrix operators that have a non-linear dependence on the at least one tissue parameter, the complexity of the optimization problem is reduced and the computation time for obtaining the quantitative MR maps is decreased. The remainder of the model, in which at least the non-linear depending part of the one or more first matrix operators is no longer present, becomes easier to solve.

Further advantages include that problem to be solved is decomposed into smaller sub-problems which require less computer memory to be solved, are faster to solve, and/or are independent and can therefore be solved in parallel, thereby allowing to obtain a solution faster on parallel computer architectures.

The remainder of the model is preferably in a matrix form or comprises one or more second matrix operators.

It is preferred to use an alternating minimization method when performing the optimization. One example of an alternating minimization method is the Alternating Direction Method of Multipliers (ADMM). Especially when factorizing the model into various operators, alternating minimization methods allow to perform the optimization with the reduced computation time.

In an embodiment, the one or more first matrix operators represent the TDMR signal at a point in time during a repetition time interval, TR, of the applied pulse sequence. The remainder of the TDMR signal model representing the signal at all other times than the point in time, can be derived by operations describing, for instance, T₂ decay and/or gradient dephasing and/or off-resonance dephasing. It is preferred that the point in time is a point during readout interval. The remaining TDMR signal may then be approximated by the remainder of the TDMR signal model by the decay/dephasing operations.

In an embodiment, one of the one or more first matrix operators represents the TDMR signal at echo time. The wording of an MR signal “at echo time” may be interpreted as at a specific time point during the readout interval. “At echo time” may more specifically indicate the point during the readout interval for which the time integral of the applied readout gradient fields is zero. In other words, it is the point for which the k-space coordinate of the readout direction is zero. Once the signal at echo time is known, the signal during the rest of the readout interval can be derived by operations describing for instance T₂ decay and gradient dephasing.

Separating the signal in these ways results a further decrease in computation time, since the remainder of the model concerns other times of the modelled MR signal such as the encoding time and the readout time. The correlations between these times within the MR signal are thus separated and the model becomes easier to optimize. It will be understood in view of the above that, where mention is made of “at echo time”, this may be replaced by “at a point in time during a repetition time interval, TR”, or by “at a point in time during a readout interval”.

Alternatively or additionally, one of remainder of the TDMR signal model represents a readout encoding matrix operator of the TDMR signal. Analogue to the advantage of the first matrix operator representing the TDMR signal at echo time, the remainder of the model including the readout encoding matrix operator of the TDMR signal also indicates the separation of the model into different time periods, namely the echo time and the rest of the readout period, thus increasing the computation efficiency.

Alternatively or additionally, the model is factorized into at least two first matrix operators that have a non-linear dependence on the at least one tissue parameter, wherein a first of the at least two first matrix operators represents the TDMR signal at echo time, and wherein a second of the at least two first matrix operators represents the readout encoding matrix operator of the TDMR signal. In this way, the two parts of the TDMR signal model that are non-linear are separated/factorized and an even larger increase in computation efficiency is obtained. In this case, the remainder of the model comprises matrix operators that are linearly dependent on the at least one tissue parameter and thus represent easy problems for the optimization.

In an embodiment, when the one or more first matrix operators comprises the TDMR signal at echo time, the performing the optimization comprises using a surrogate predictive model wherein a TDMR signal is computed at echo time only based on the TDMR signal at echo time, wherein the surrogate predictive model outputs the TDMR signal at echo time and one or more TDMR signal derivatives at echo time with respect to each of the at least one tissue parameter within the sample. Although the term “surrogate predictive model” is used, this may also be referred to as a “predictive model”. “Surrogate” here indicates a “replacement” for the physical (Bloch) equation solvers, which are notoriously slow. “Surrogate” thus indicates a different computational model which is not necessarily derived from physical principles but which is still able to return the response of the physical system in an accurate and faster way.

In this way, only for the most non-linear part of the TDMR signal model, being the TDMR signal at echo time, the derivatives are calculated and therefore the computation time is reduced. The combination in the method of the matrix factorization of the model and the use of a (surrogate) predictive model achieves up to at least a two order of magnitude acceleration in reconstruction times compared to the state-of-the-art MR-STAT. For example, when using a neural network based predictive model, high-resolution 2D datasets can be reconstructed within 10 minutes on a desktop PC, thereby drastically facilitating the application of MR-STAT in the clinical work-flow.

The surrogate predictive model is readily implementable and preferably implemented independent on the type of acquisition (e.g. Cartesian, radial, etc.).

In an embodiment, the TDMR signal model is a volumetric signal model and comprises a plurality of voxels, wherein preferably the step of performing optimization is done iteratively for each line in a phase encoding direction of the voxels of the TDMR signal model. One advantage of performing the optimization for each line is that the problem to be solved is decomposed into smaller sub-problems which require less computer memory to be solved, are faster to solve and are usually independent and can therefore be solved in parallel, thereby allowing to obtain a solution faster on parallel computing architectures.

In an embodiment, the TDMR signal at echo time is a compressed TDMR signal at echo time for each line of voxels, wherein the TDMR signal at echo time is compressed for each voxel, the TDMR signal model preferably comprising a corresponding compression matrix for the compressed TDMR signal at echo time. When another point in time during TR is taken instead of the echo time as described above, the compression matrix relates to that other point in time.

Alternatively or additionally, the remainder of the TDMR signal model is linearly dependent or independent on the at least one tissue parameter and comprises a diagonal phase encoding matrix (preferably for each of the lines of voxels), and preferably the compression matrix for the TDMR signal at echo time.

In an embodiment, the optimization with an objective function and constraints is representable by:

$${min}_{α} \frac{1}{2} {‖ D - {\sum }_{i = 1}^{{N}_{y}} {C}_{i}^{p} UY ( {α}_{i} ) {C}^{r} ( {α}_{i} ) ‖}_{F}^{2} \qquad ( Eq . 1 )$$

wherein;
αᵢ denotes the at least one tissue parameter for the ith line of voxels in the phase encoding direction;
Cᵢ^{p}∈ [symbol] ^{N}^{_{Tr}}^{×N}^{_{Tr}} is the diagonal phase encoding matrix for the ith line of voxels in the phase encoding direction;
U∈ [symbol] ^{N}^{_{Tr}}^{×N}^{_{Eig}} is the compression matrix for the TDMR signal at echo time, N_{Tr} being a number of RF pulses and N_{Eig} being a length of the compressed TDMR signal at echo time;
Y(αᵢ)∈ [symbol] ^{N}^{_{Eig}}^{×N}^{ₓ} is the compressed echo time TDMR signal for the ith line in the phase encoding direction of voxels, wherein each column of Y(αᵢ) is the compressed TDMR signal for one voxel in the ith line;
C^{r}(αᵢ)∈ [symbol] ^{N}^{ₓ}^{×N}^{_{Read}} is the readout encoding matrix for the ith line in the phase encoding direction of voxels;
D∈ [symbol] ^{N}^{_{Tr}}^{×N}^{_{Read}} is the TDMR signal emitted from the sample in a matrix format, N_{Read} being a number of readout points every TR;
   N_{y} represents the number of voxels or rows of voxels in the phase encoding direction.

Alternatively or additionally, the optimization with an objective function and constraints is representable by:

$${min}_{α , Z , W} {ℒ}_{λ} ( α , Z , W ) \qquad ( Eq . 2 )$$

wherein;
[symbol] _{λ} is a Lagrangian with λ representing the Lagrange multiplier;
α represents the at least one tissue parameter;
Z represents an alternative or slack variable; and
W represents a dual variable for Z.

In particular, the non-linear optimization problem is represented by:

$${min}_{α , Z , W} {L}_{λ} ( α , Z , W ) = {min}_{α , Z , W} \frac{1}{2} {‖ D - {\sum }_{i = 1}^{{N}_{y}} {C}_{i}^{p} {UZ}_{i} ‖}_{F}^{2} + \frac{λ}{2} {\sum }_{i = 1}^{{N}_{y}} {‖ Y ( {α}_{i} ) {C}^{r} ( {α}_{i} ) - {Z}_{i} + {W}_{i} ‖}_{F}^{2} - \frac{λ}{2} {\sum }_{i = 1}^{{N}_{y}} {‖ {W}_{i} ‖}_{F}^{2} \qquad ( Eq . 3 )$$

wherein;
Wᵢ∈ [symbol] ^{N}^{_{Eig}}^{×N}^{_{Read}} represents a dual variable for Zᵢ;
αᵢ denotes the at least one tissue parameter for the ith line of voxels in the phase encoding direction;
Cᵢ^{p}∈ [symbol] ^{N}^{_{Tr}}^{×N}^{_{Tr}} is the diagonal phase encoding matrix for the ith line of voxels in the phase encoding direction;
U∈ [symbol] ^{N}^{_{Tr}}^{×N}^{_{Eig}} is the compression matrix for the TDMR signal at echo time, N_{Tr} being a number of RF pulses and N_{Eig} being a length of the compressed TDMR signal at echo time;
Y(αᵢ)∈ [symbol] ^{N}^{_{Eig}}^{×N}^{ₓ} is the compressed echo time TDMR signal for the ith line in the phase encoding direction of voxels, wherein each column of Y(αᵢ) is the compressed TDMR signal for one voxel in the ith line;
C^{r}(αᵢ)∈ [symbol] ^{N}^{ₓ}^{×N}^{_{Read}} is the readout encoding matrix for the ith line in the phase encoding direction of voxels;
D∈ [symbol] ^{N}^{_{Tr}}^{×N}^{_{Read}} is the TDMR signal emitted from the sample in a matrix format, N_{Read} being a number of readout points every TR;
N_{y} represents the number of voxels or rows of voxels in the phase encoding direction.

Alternatively or additionally, the step ii) of performing optimization comprises using a set or plurality of sub-sets of equations based on the factorized model, each equation (or sub-set) of the set of equations being arranged to obtain an updated respective (sub-set) variable by performing optimization in a cyclic manner. The cyclic manner may be that one variable or sub-set is optimized while all the other variables or sub-sets are kept fixed, then another variable or sub-set is optimized while the other variables or sub-sets are kept fixed, then another variable or sub-set and so on, and to keep iterating this alternating scheme until an optimization objective is reached.

For instance: first keep T₂, B₁, and PD fixed and solve for T₁. Then keep T₁, B₁ and PD fixed and solve for T₂, etc. In this example there are no auxiliary nor dual variables but there is still an alternation.

Another example would be to group unknowns in a spatial way, for instance, each line on the image representing a group. Then, solve for T₁, T₂, B₁, PD of a specific line and the rest/other lines is kept fixed. Then solve for T₁, T₂, B₁, PD of another line and keep the rest/other lines fixed etc. Again, no auxiliary nor dual variables are involved.

Alternatively or additionally, the step ii) of performing optimization comprises:
using a set of equations based on the factorized model, each equation of the set of equations being arranged to obtain an updated respective variable, wherein the variables comprise a first variable, or set of variables, representing an auxiliary or slack variable, a second variable, or set of variables, representing the at least one tissue parameter and a third variable, or set of variables, representing a dual variable, the minimizing comprising;
   iii) obtaining an update value for the first variable while keeping the other variables fixed;
   iv) then obtaining an update for the second variable while keeping the other variables fixed;
   v) then obtaining an update for the third variable while keeping the other variables fixed, and
   vi) repeating steps iii), iv), and v) until a difference between the TDMR signal model and the measured TDMR signal using the updated values of the respective variables as the respective input until a difference between the updated second variable and the input second variable is smaller than a predefined threshold or until a predetermined number of repetitions is completed, thereby obtaining a final updated set of TDMR signal model parameters,

It is preferred that each equation is configured to obtain an updated variable for a line of voxels in the phase encoding direction.

Alternatively or additionally, it is preferred that the minimizing comprises estimating an initial set of the variables and thereafter sequentially performing the steps iii), iv) and v) according to;
iii) obtaining an updated value for the first variable using the estimated initial set of variables as input;
iv) obtaining an updated value for the second variable using the updated first variable and the initial third variable as input;
v) obtaining an updated value for the third variable using the updated first variable and the updated second variable as input, and

the step vi) of repeating is performed by using the updated values of the respective variables as the respective input until a difference between the updated second variable and the input second variable is smaller than a predefined threshold.

Preferably, the step ii) of performing non-linear optimization comprises, for the (k+1)^{th} iteration:
obtaining the updated value for the first variable according to

$$\begin{matrix}{Z}^{( k + 1 )} = arg {min}_{Z} {ℒ}_{λ} ( {α}^{( k )} , Z , {W}^{( k )} ) ; \\ = {( {C}^{*} C + λ I )}^{( - 1 )} ( {C}^{*} D + λ {M}^{( k )} + λ {W}^{( k )} ) ,\end{matrix}$$

wherein I is an identity matrix,

wherein

$$C = [ {C}_{1}^{p} U , {C}_{2}^{p} U , … , {C}_{{N}_{y}}^{p} U ] ∈ {ℂ}^{{N}_{TR} \times ( {N}_{eig} * {N}_{y} )} , \\ and {M}^{( k )} = [ \begin{matrix}Y ( {α}_{1}^{( k )} ) {C}^{r} ( {α}_{1}^{( k )} ) \\ Y ( {α}_{2}^{( k )} ) {C}^{r} ( {α}_{2}^{( k )} ) \\ … \\ Y ( {α}_{{N}_{y}}^{( k )} ) {C}^{r} ( {α}_{{N}_{y}}^{( k )} )\end{matrix} ] ;$$

obtaining the updated value for the second variable according to

α^{(k+t)}=argmin_{α} [symbol] _{λ}(α,Z^{(k+1)},W^{(k)});

αᵢ^{(k+1)}=argmin_{α}_{ᵢ}∥Y(αᵢ)C^{r}(αᵢ)−Zᵢ^{(k+1)}+Wᵢ^{(k)}∥_{F}² for i∈[1,N_{y}]; and
obtaining the updated value for the third variable according to

Wᵢ^{(k+1)}=Wᵢ^{(k)}+Y(αᵢ^{(k+1)})C^{r}(αᵢ^{(k+1)})−Zᵢ^{(k+1)}.

In an embodiment, the obtaining the updated value for the second variable is performed by solving N_{y} separate nonlinear problems using a trust-region method.

According to yet another embodiment, the step ii) of performing optimization comprises using the Alternating Direction Method of Multipliers (ADMM).

In an embodiment, the surrogate predictive model is implemented as a neural network, a Bloch equation based model or simulator, or a dictionary based model.

Preferably, the neural network is implemented as a deep neural network or a recurrent neural network, wherein, when the neural network is implemented as the deep neural network, the deep neural network is preferably fully connected. A recurrent neural network, for instance, allows for efficient inclusion of additional parameters such as the (time dependent) flip angle. This does not exclude that other types of neural network may also be implemented with such other parameters.

In an embodiment, the at least one tissue parameter comprises any one of a T1 relaxation time, T2 relaxation time, T2* relaxation time and a proton density, or a combination thereof.

In another embodiment of the method, the TDMR signal model is a Bloch based volumetric signal model.

The applied pulse sequence may for example comprise a gradient encoding pattern and/or a radio frequency excitation pattern.

It is an option that the TDMR signal model parameters further comprise parameters describing the applied pulse sequence.

The applied pulse sequence may be configured to yield any one of a Cartesian acquisition, radial acquisition, or spiral acquisition.

In an embodiment, the applied pulse sequence comprises a gradient encoding pattern and/or a radio frequency excitation pattern, wherein preferably the gradient encoding pattern of the applied pulse sequence is configured to yield a Cartesian acquisition, such that a corresponding point-spread function only propagates in a phase encoding direction.

According to a second aspect, there is provided a device for determining a spatial distribution of at least one tissue parameter within a sample based on a time domain magnetic resonance, TDMR, signal emitted from the sample after excitation of the sample according to an applied pulse sequence, the device comprising a processor which is configured to:

i) determine a TDMR signal model to approximate the emitted time domain magnetic resonance signal, wherein the TDMR signal model is dependent on TDMR signal model parameters comprising the at least one tissue parameter within the sample,

wherein the model is factorized into one or more first matrix operators that have a non-linear dependence on the at least one tissue parameter and a remainder of the TDMR signal model;

ii) perform optimization with an objective function and constraints based on the first matrix operators until a difference between the TDMR signal model and the TDMR signal emitted from the sample is below a predefined threshold or until a predetermined number of repetitions is completed, in order to obtain an optimized or final set of TDMR signal model parameters; and

iii) extract from the optimized or final set of TDMR signal model parameters the spatial distribution of the at least one tissue parameter.

It will be apparent that any advantage relating to the above first aspect is readily applicable to the present device. Also any embodiments, options, alternatives, etc., described above for the method according to the first aspect can be readily applied to the device.

According to a third aspect, there is provided a method of obtaining at least one magnetic resonance, MR, signal derivative with respect to at least one respective tissue parameter of an MR signal, the MR signal being emitted from a sample after excitation of the sample according to an applied pulse sequence, the method comprising performing an iterative non-linear optimization with an objective function and constraints in order to obtain an optimized or final value for the at least one MR signal derivative with respect to the at least one respective tissue parameter, wherein the performing of the optimization comprises, for each iteration of the non-linear optimization, using a predictive model receiving the at least one tissue parameter as input and outputting the at least one MR signal derivative with respect to each of the at least one time dependent parameter within the sample.

The use of the predictive model in general to MR signal calculations where derivatives are required allows to effectively reduce the computation time.

Some examples of where the derivatives of an MR signal w.r.t. the tissue parameters are required outside of MR-STAT are as follows. A first example 1 relates to so-called MR fingerprinting, in particular dictionary-free MR Fingerprinting reconstructions, see for example: Sbrizzi, A., Bruijnen, T., van der Heide, O., Luijten, P., & van den Berg, C. A. (2017). Dictionary-free MR Fingerprinting reconstruction of balanced-GRE sequences, arXiv preprint arXiv:1711.08905. Another example is optimal experiment design for MR fingerprinting, see e.g. Zhao, B et al., “Optimal experiment design for magnetic resonance fingerprinting: Cramer-Rao bound meets spin dynamics”, IEEE transactions on medical imaging 38(3), 2018, 844-861. For instance, to obtain an optimal time varying Flipangle train for use in the MR fingerprinting method, derivatives of the magnetization w.r.t. parameters such as the tissue parameters T₁, T₂, etc., are required.

A third example relates to optimal experiment design for quantitative MR, see e.g. Teixeira, R. et al., “Joint system relaxometry (JSR) and Cramer-Rao lower bound optimization of sequence parameters: a framework for enhanced precision of DESPOT T1 and T2 estimation”, Magnetic resonance in medicine 79(1), 2018, 234-245. Also here derivatives of the magnetization w.r.t. parameters such as the tissue parameters T₁, T₂, etc., are required.

In view of the above, the predictive model(s), in particular the neural networks, of the present application is applicable in general for MR signals, and not only for time domain MR signals.

The present method may also be applied to obtain the derivatives as required in the method described in NL2022890, e.g. a method according to claim 1 thereof, in particular for computing the (approximate) Hessian matrix.

In an embodiment, the predictive model is implemented as a neural network configured to accept the at least one tissue parameter and parameters relating to the applied pulse sequence as input parameters, wherein the neural network is preferably a deep neural network or a recurrent neural network.

Alternatively or additionally, the predictive model is implemented as a dictionary based predictive model or a Bloch equation based model.

Alternatively or additionally, the predictive model is arranged to further predict or compute values of a magnetization and one or more derivatives thereof with respect to respective ones of the at least one tissue parameter within the sample.

Alternatively or additionally, the at least one tissue parameter comprises one or any combination of a T₁ relaxation time, a T₂ relaxation time, a T₂* relaxation time and a proton density, PD.

In an embodiment, the predictive model is arranged to output the MR signal for echo time only. Alternatively, the predictive model may be arranged to output the MR signal for a point in time during a repetition time, TR, only or at a point in time during a readout interval only.

Alternatively or additionally, the MR signal is a time domain magnetic resonance, TDMR, signal.

It will be apparent that the embodiments and respective advantages relating to the (surrogate) predictive model of the other aspects of the present disclosure are applicable to the present predictive model.

According to a fourth aspect, there is provided a device for obtaining at least one magnetic resonance, MR, signal derivative with respect to at least one respective tissue parameter of an MR signal, the MR signal being emitted from a sample after excitation of the sample according to an applied pulse sequence, the device comprising a processor configured to perform an iterative non-linear optimization with an objective function and constraints in order to obtain an optimized or final value for the at least one MR signal derivative with respect to the at least one respective tissue parameter, wherein the processor is configured to perform the optimization, for each iteration of the non-linear optimization, by using a predictive model receiving the at least one tissue parameter as input and outputting the at least one MR signal derivative with respect to each of the at least one time dependent parameter within the sample.

It will be apparent that any advantage relating to the above third aspect is readily applicable to the present device. Also any embodiments, options, alternatives, etc., described above for the method according to the third aspect can be readily applied to the device according to the fourth aspect.

According to a fifth aspect, there is provided, a computer program product comprising computer-executable instructions for performing the method of any one of the first or third aspects, when the program is run on a computer.

### BRIEF DESCRIPTION OF THE DRAWINGS

The accompanying drawings are used to illustrate presently preferred non-limiting exemplary embodiments of devices of the present disclosure. The above and other advantages of the features and objects of the disclosure will become more apparent and the aspects and embodiments will be better understood from the following detailed description when read in conjunction with the accompanying drawings, in which:

FIG. 1 is a schematic drawing of an implementation of a factorized TDMR signal model in accordance with the present patent disclosure;

FIG. 2 is a schematic drawing of a neural network implementation of a surrogate model for obtaining a magnetization and derivatives thereof in accordance with the present patent disclosure;

FIG. 3A is a schematic drawing of a neural network implementation of the network of FIG. 2;

FIG. 3B is a schematic drawing of a detailed structure of Networks 1-4 of FIG. 3A;

FIG. 4 is a schematic drawing of an alternative neural network implementation of a surrogate model for obtaining a magnetization and derivatives thereof in accordance with the present patent disclosure;

FIG. 5 shows plots results of various scans in a summarized manner and a table showing a construction time comparison, the results being obtained in accordance with the present patent disclosure and compared to related art methods;

FIG. 6 shows imaging results of 12 gel tubes with different T₁ and T₂ values obtained in accordance with the present patent disclosure and compared to related art methods;

FIG. 7 shows imaging results of a human brain obtained in accordance with the present patent disclosure and compared to related art methods;

FIG. 8 is a block diagram of an exemplary device for performing determining a spatial distribution according to the present patent disclosure; and

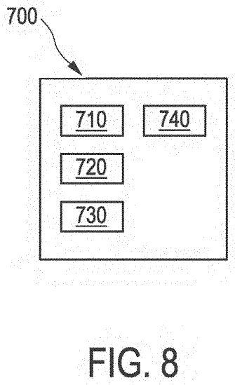

FIG. 9 is a schematic plot of an example measurement of an induced demodulated magnetic potential (emf) versus time wherein various parameters are defined.

### DESCRIPTION

In MR-STAT, parameter maps are reconstructed by iteratively solving the large scale, non-linear problem

$$\hat{α} = arg {min}_{α} \frac{1}{2} {‖ d - s ( α ) ‖}_{2}^{2} , \qquad ( 1 )$$

where d is the data in time domain, a denotes all parameter maps, and s is the volumetric signal model, such as a Bloch equation based signal model. Recent improvements have been obtained and are the subject of at present pending application NL2022890, which is incorporated herein by reference in its entirety. However, MR-STAT reconstructions still lead to long computation times because of the large scale of the problem, requiring a high performance computing cluster for application in a clinical work-flow.

In an embodiment, the MR-STAT reconstructions are accelerated by following two strategies, namely: 1) adopting an Alternative Direction Method of Multipliers (ADMM) and 2) computing the signal and derivatives by a surrogate model. Although it is preferred to apply these two strategies simultaneously, it is possible to apply these two strategies independently in order to obtain a reduced reconstruction time. When applied simultaneously, the new algorithm achieves a two order of magnitude acceleration in reconstructions with respect to the state-of-the-art MR-STAT. A high-resolution 2D dataset is reconstructed within 10 minutes on a desktop PC. This thus facilitates the application of MR-STAT in the clinical work-flow.

### Example of Implementation of an Alternating Minimization Method for MR-STAT: ADMM

The general MR-STAT optimization problem can be written as:

$${min}_{α} \frac{1}{2} {‖ d - s ( α ) ‖}_{2}^{2} = {min}_{α} \frac{1}{2} {‖ d - {\sum }_{j = 1}^{{N}_{x} * {N}_{y}} \hat{s} ( {α}_{j} ) ‖}_{2}^{2} . \qquad ( 1 )$$

Problem Dimension:
N_{y}: Number of voxel in phase encoding (Y) direction;
Nₓ: Number of voxel in readout encoding (X) direction;
N_{Tr}: Number of RF pulses;
N_{Read}: Number of readout points every TR (repetition time);
N_{Eig}: Length of the compressed echo time signal;

A vector definition for problem (1) is as follows:
d∈ [symbol] ^{N}^{_{Tr}}^{*N}^{_{Read}}^{×1} measured signal;
s(αⱼ)∈ [symbol] ^{N}^{_{Tr}}^{*N}^{_{Read}}^{×1} computed magnetization signal for voxel j with quantitative parameter αⱼ.

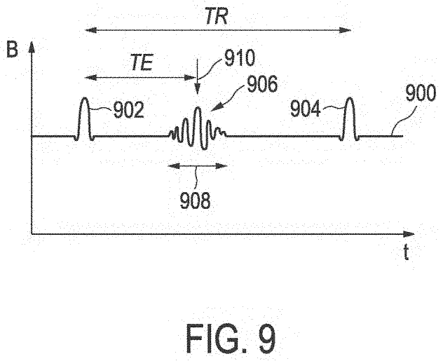

Referring now to FIG. 9, there are shown two transmitted RF waveforms 902 and 904 and the received signal waveform 906. The repetition time interval TR is defined as the time between the excitation pulses such as pulses 902 and 904 in example data 900. TE is defined as the time between an excitation pulse and subsequent echo such as the TE indicated between echo 906 and pulse 902 in FIG. 9. What is referred to above and below as “at echo time” refers to at a specific time point during the readout interval 908. “At echo time” may here indicate the point 910 during the readout interval 908 for which the time integral of the applied readout gradient fields is zero. In other words, it is the point for which the k-space coordinate of the readout direction is zero. For instance, in a Cartesian acquisition, the echo-time coincide with the middle of the readout. Once the signal at echo time is known, the signal during the rest of the readout interval can be derived by operations describing for instance T₂ decay and gradient dephasing.

Returning to the example implementation of the alternating minimization method, especially when assuming Cartesian sampling, the original volumetric signal s (Eq 1) can be factorized into different matrix operators, leading to the following form,

$$\hat{α} = arg {min}_{α} \frac{1}{2} {‖ D - {\sum }_{i = 1}^{{N}_{y}} {C}_{i}^{p} UY ( {α}_{i} ) {C}^{r} ( {α}_{i} ) ‖}_{F}^{2} . \qquad ( 2 )$$

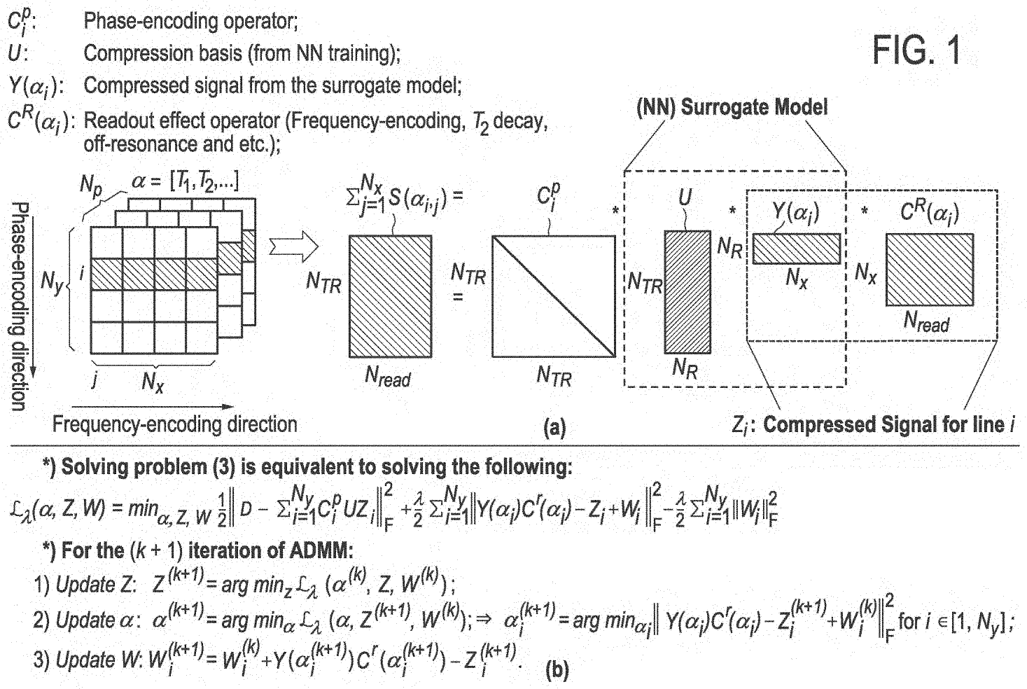

A graphic illustration of the new problem (2) and the explanation of the operators is shown in FIG. 1. Eq. 2 represents a matrix definition of the optimization of Eq. 1. The parameters/Matrices are defined as follows:
D∈ [symbol] ^{N}^{_{Tr}}^{×N}^{_{Read}}, measured signal which is a matrix format of d in (1);
U∈ [symbol] ^{N}^{_{Tr}}^{×N}^{_{Eig}}, compression matrix for echo time signal.
Y(αᵢ)∈ [symbol] ^{N}^{_{Eig}}^{×N}^{ₓ}, compressed echo time signal for the ith coordinate of voxels in the phase encoding direction; each column of Y(αᵢ) is the compressed signal for one voxel in the ith line; Y is nonlinear with respect to a.
C^{r}(αᵢ)∈ [symbol] ^{N}^{_{Tr}}^{*N}^{_{Read}}, readout encoding matrix for the ith line of voxel, it consists of different factors, including the readout gradient encoding, the T₂ decay, the off-resonance rotation and the proton density scaling; each row of C^{r}(αᵢ) expands the echo time signal into the whole readout line signal; Although C^{r} depends on α, its relation with a can be expressed in analytical closed form. Y can be computed using numerical recurrent schemes.
Cᵢ^{P}UY(αᵢ)C^{r}(αᵢ), the four components together, compute the whole magnetization signal for one line (i.e. the i-th coordinate in the phase encoding direction) of the image; the first two components, Cᵢ^{p} and U, do not depend on α (i.e. parameters to be reconstructed), and they only depend on the scanning sequence, therefore separating these matrix operators from the other two α-dependent components achieves an increase in efficiency of the reconstruction;
The two matrices UY(αᵢ) together, compute the magnetization for the ith line of voxel at echo time; They can be computed from e.g. a fully-connected neural network as described below. They can also be computed by using a Bloch equation based model or a dictionary-based method, as described in further detail below.

In the above equation (2), and if used equivalently elsewhere in the present disclosure, F indicates that the norm (∥ . . . ∥) is the Frobenius norm.

We reformulate problem (2) as the following constrained problem

$$\hat{α} = arg {min}_{α} \frac{1}{2} {‖ D - {\sum }_{i = 1}^{{N}_{y}} {C}_{i}^{p} {UZ}_{i} ‖}_{F}^{2} subject to Y ( {α}_{i} ) {C}^{r} ( {α}_{i} ) - {Z}_{i} = 0 for i ∈ [ 1 , {N}_{y} ] , \qquad ( 3 )$$

by adding slack or auxiliary variable Zᵢ. Adding to eq. (3) the non-linear constraints into the objective function to obtain an Augmented Lagrangian:

$$= {min}_{α , Z , Y} \frac{1}{2} {‖ D - {\sum }_{i = 1}^{{N}_{y}} {C}_{i}^{p} {UZ}_{i} ‖}_{F}^{2} + {\sum }_{i = 1}^{{N}_{y}} {〈 {Y}_{i} , Y ( {α}_{i} ) {C}^{r} ( {α}_{i} ) - {Z}_{i} 〉}_{F} + \frac{λ}{2} {\sum }_{i = 1}^{{N}_{y}} {‖ Y ( {α}_{i} ) {C}^{r} ( {α}_{i} ) - {Z}_{i} ‖}_{F}^{2}$$

Augmented lagrangian, viz. the nonlinear constraints are added into the objective function

$$= {min}_{α , Z , W} \frac{1}{2} {‖ D - {\sum }_{i = 1}^{{N}_{y}} {C}_{i}^{p} {UZ}_{i} ‖}_{F}^{2} + \frac{λ}{2} {\sum }_{i = 1}^{{N}_{y}} {‖ Y ( {α}_{i} ) {C}^{r} ( {α}_{i} ) - {Z}_{i} + {W}_{i} ‖}_{F}^{2} - \frac{λ}{2} {\sum }_{i = 1}^{{N}_{y}} {‖ {W}_{i} ‖}_{F}^{2}$$

scaled Augmented Lagrangian, algebraic simplification

$$= {min}_{α , Z , W} {ℒ}_{λ} ( α , Z , W ) \qquad ( 4 )$$

The introduced parameters/Matrices are defined as:
Zᵢ∈ [symbol] ^{N}^{_{Eig}}^{×N}^{_{Read}}, compressed signal for the ith line of voxel;
Wᵢ∈ [symbol] ^{N}^{_{Eig}}^{×N}^{_{Read}}, dual variable for Z₁;
Z=[Z₁; Z₂; . . . ; Z_{N}_{_{y}}]∈ [symbol] ^{N}^{_{Tr}}^{×N}^{_{Read}} stack small matrices together; Similar for W.

The corresponding alternating update scheme is as follows.

For equation (4), the three variables α, Z, W are obtained sequentially during an ADMM iteration. Reference is made here to Boyd, S., Parikh, N., Chu, E., Peleato, B., & Eckstein, J. (2011). Distributed optimization and statistical learning via the alternating direction method of multipliers, Foundations and Trends in Machine learning, 3(1), 1-122, which is incorporated herein by reference in its entirety.

The following steps are performed, after obtaining an initial value for the three variables. Then, for the (k+1)th iteration:

1. Update Z: Z^{(k+1)}=argmin_{z} [symbol] _{λ} (α^{(k)}, Z, W^{(k)});

This is a linear problem and the closed form solution is given as:

Z^{(k+1)}=(C*C+λl)⁽⁻¹⁾(C*D+λM^{(k)}+λW^{(k)}),

wherein I is an identity matrix, and the definitions of C and M^{(k)} are given by

$$C = [ {C}_{1}^{p} U , {C}_{2}^{p} U , … , {C}_{{N}_{y}}^{p} U ] ∈ {ℂ}^{{N}_{TR} \times ( {N}_{eig} * {N}_{y} )} , \\ and {M}^{( k )} = [ \begin{matrix}Y ( {α}_{1}^{( k )} ) {C}^{r} ( {α}_{1}^{( k )} ) \\ Y ( {α}_{2}^{( k )} ) {C}^{r} ( {α}_{2}^{( k )} ) \\ … \\ Y ( {α}_{{N}_{y}}^{( k )} ) {C}^{r} ( {α}_{{N}_{y}}^{( k )} )\end{matrix} ] ;$$

This linear system can be solved also by standard iterative algorithms for linear least-squares problems.

2. Update α: α^{(k+1)}=argminₐ [symbol] _{λ}(α, Z^{(k+1)}, W^{(k)});

αᵢ^{(k+1)}=argmin_{α}_{ᵢ}∥Y(αᵢ)C^{r}(αᵢ)−Zᵢ^{(k+1)}+Wᵢ^{(k)}∥_{F}² for i∈[1,N_{y}], (5)

in this sub-step, N_{y} separate nonlinear problems can be solved for instance by trust-region method;

3. Update W: Wᵢ^{(k+1)}=Wᵢ^{(k)}+Y(αᵢ^{(k+1)})C^{r}(αᵢ^{(k+1)})−Zᵢ^{(k+1)}, this is just simple linear computation.

In the above step 2, a is updated by solving the nonlinear problem indicated in FIG. 1(b).

αᵢ^{(k+1)}=argmin_{α}_{ᵢ}∥Y(αᵢ)C^{r}(αᵢ)−Zᵢ^{(k+1)}+Wᵢ^{(k)}∥_{F}² for i∈[1,N_{y}].

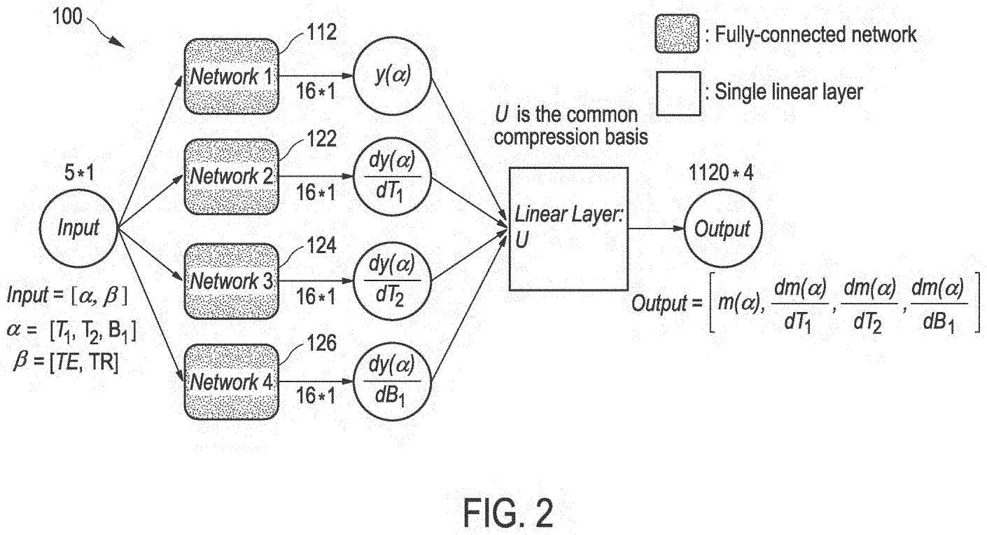

In step 2, Y(αᵢ) can be output of Network 1, 112, of FIG. 2, which is part of the surrogate model 100. In order to solve this optimization problem by non-linear optimization methods, including, for example, gradient descent, Gauss-Newton, Trust-region, the derivatives w.r.t. the inputs α, namely dY(αᵢ)/dαᵢ, are also needed, and these derivatives are the outputs of the other Networks 2 to 4, labeled as 122, 124 and 126 respectively, in FIG. 2. Alternative methods for calculating Y(αᵢ) and its derivatives w.r.t. the inputs α are given below.

The C^{r}(αᵢ) matrix models the MR signal evolution during one readout. The preferred surrogate model only computes the MR signal at echo time, and the C^{r}(αᵢ) matrix is used in order to compute MR signals at all sample time points during the readout. The C^{r}(αᵢ) matrix describes the effects of (a) the frequency encoding gradient; (b) the T2 decay and (c) the B0 dephasing during the readout. These effects can be mathematically expressed in standard exponential and phase terms.

In summary, in the above ADMM scheme, step (1) solves a linear problem and step (2) solves N_{y} small parallelizable nonlinear problems using the compressed signal, therefore substantially reducing the computational complexity w.r.t. the original MR-STAT.

The above ADMM approach is shown graphically in FIG. 1, showing the TDMR model factorization and the corresponding ADMM algorithm. FIG. 1(a) shows a graphic illustration of Eq. (2). The four operators are shown which together generate the full model: C^{p}, U, Y(αᵢ) and C^{r}(αᵢ). FIG. 1(b) shows the ADMM algorithm with data d formatted as a matrix D. In step (1), the compressed signals Z are computed by solving a linear problem. In step (2), quantitative maps are obtained by solving separate nonlinear problems using a trust-region method.

The presently described ADMM scheme is implemented as an example for Cartesian acquisition but it will be apparent using the knowledge of the present disclosure that the ADMM scheme can be readily adapted for other kind of acquisitions.

Example with Linear Constraint

The above Eq. 3 is an example of a non-linear constrained problem. Another example for implementation is to have a linear constraint problem, as follows:

$${min}_{α} \frac{1}{2} {‖ D - {\sum }_{i = 1}^{{N}_{y}} {C}_{i}^{p} UM ( {α}_{i} ) {C}^{r} ( {α}_{i} ) ‖}_{F}^{2} \qquad ( 6 )$$

$$= {min}_{α , Z} \frac{1}{2} {\sum }_{i = 1}^{{N}_{y}} {‖ M ( {α}_{i} ) {C}^{r} ( {α}_{i} ) - {Z}_{i} ‖}_{F}^{2} subject to {\sum }_{i = 1}^{Ny} {C}_{i}^{p} {UZ}_{i} - D = 0$$

$$( Linear Constraint )$$

$$= {min}_{α , Z , W} \frac{1}{2} {\sum }_{i = 1}^{{N}_{y}} {‖ M ( {α}_{i} ) {C}^{r} ( {α}_{i} ) - {Z}_{i} ‖}_{F}^{2} + \frac{λ}{2} {‖ {\sum }_{i = 1}^{Ny} {C}_{i}^{p} {UZ}_{i} - D + W ‖}_{F}^{2} - \frac{λ}{2} {‖ W ‖}_{F}^{2}$$

$$( Linearized Augmented Lagrangian )$$

$$= {min}_{α , Z , W} {ℒ}_{λ} ( α , Z , W ) .$$

Comparing to Eq. 3, this is another way of approaching the optimization problem. Eq. 3 uses the nonlinear relationships as non-linear constraints in the first step, the above uses the linear relationship as a linear constraint. An equivalent approach to the above steps of the ADMM iterations are followed for this linear constraint variant.

Regularization

In order to reconstruct better, less noisy images, different regularization terms can be added into the optimization problems for different parameter images (e.g., T₁, T₂, the real part and imaginary part of the proton density (resp. real(PD) and imag(PD))). In order to solve the problem with such regularization terms, additional alternative variable and splitting schemes are added to the above Eq. (4):

$${min}_{α , Z , W} {ℒ}_{λ} ( α , Z , W ) + {\sum }_{j = 1}^{{N}_{par}} {γ}_{j} R ( {α}_{j} ) \qquad ( 7 )$$

$$= {min}_{α , β , Z , W} {ℒ}_{λ} ( α , Z , W ) + {\sum }_{j = 1}^{{N}_{par}} {γ}_{j} R ( {β}_{j} ) subject to {β}_{j} - {α}_{j} = 0 for j ∈ [ 1 , {N}_{par} ] ,$$

$$= {min}_{α , β , Z , W , V} {ℒ}_{λ} ( α , Z , W ) + {\sum }_{j = 1}^{{N}_{par}} {γ}_{j} R ( {β}_{j} ) + {\sum }_{j = 1}^{{N}_{par}} ( \frac{{η}_{j}}{2} {‖ {β}_{j} - {α}_{j} + {V}_{j} ‖}_{2}^{2} - \frac{{η}_{j}}{2} {‖ {V}_{j} ‖}_{2}^{2} ) .$$

Here, αⱼ here is the parameter image for the jth parameter (e.g. T₁, T₂, etc.), and the number of parameters which need regularization is Nₚₐᵣ; The regularization term R(αᵢ) is the regularization term for the jth parameter image, and R is any regularization such as L2 regularization or Total Variation (TV) regularization; γⱼ and ηⱼ are carefully chosen for different parameter images, in order to achieve optimal reconstructed image quality.

Thereafter, the alternating update scheme is also used to sequentially update all the parameters: 1. Update Z and βⱼ⇒2. Update α⇒3. Update W and V. The adding regularization terms has almost no impact to the computation time.

Neural Network Surrogate MR signal Model

Since MR-STAT, but also some configuration parameters of other quantitative MRI techniques, are obtained/solved by a derivative-based iterative optimization scheme, both the magnetization and its derivatives with respect to all reconstructed parameters are computed at each iteration using an MR signal model such as an Extended Phase Graph, EPG, model as described in Weigel, Matthias. Journal of Magnetic Resonance Imaging 41.2 (2015): 266-295, or a Bloch equation based model. To accelerate the signal computation, a neural network (NN) is designed and trained to learn to compute the signal and derivatives with respect to the tissue parameters (α). Preferably, the NN is designed for either balanced or gradient spoiled sequence. The NN architecture according to an embodiment is shown in FIG. 2. The NN consists of separate blocks for computing the compressed magnetization and derivatives, and one final shared linear layer as a learnable compression operator which reduces the dimensionality of the problem to a low rank. In the preferred embodiment, the rank=16.

In other words, the input of the NN is a combination of reconstructed parameters (T1,T2,B1,B0) and optionally time-independent sequence parameters such as TR and TE and time-dependent parameters such as flip angles. The output is the time-domain MR signal (transverse magnetization) and its derivatives w.r.t. to the parameters of interest, such as the tissue parameters T₁ and T₂.

The network is split in two parts: the first part includes (sub-)Network 1 to Network 4, and they learn the MR signal and their derivatives in a compressed (low-rank) domain. In this specific example, since there are three types of non-linear parameters to reconstruct, namely, T₁,T₂ and B₁, there are three different partial derivatives that are calculated. Thus, three networks for derivatives, i.e. Networks 2, 3 and 4 are present in the present example. In the case that less, more and/or other parameters need to be reconstructed, than less, more and/or other derivative Networks will be needed. If one does not need to reconstruct, say, B1, then only two derivative Networks are needed. In general, there is one (sub-)network for the signal and N (sub-)networks for the derivatives of each of the N parameters to be reconstructed.

Each of the Networks 1-4 in an embodiment has four fully connected layers with ReLU activation function. The second part of the network is the single linear layer which is represented by the compression matrix U. The matrix U is learned during the training. The first part of the network is preferably used in step 2 in the ADMM algorithm (for computing Y and dY/dα), and the second part of the network (linear step, i.e. matrix U) is used in step 1 of the ADMM algorithm.

Several embodiments of neural network architectures are provided. It will be understood that other network architectures may also perform similar to the below described embodiments.

One described embodiment is a Deep Neural Network having several layers comprising a combinations of, for instance, non-linear activation functions, convolution layers, drop-out layers, max-pooling (or variants) layers, linear combination layers and fully-connected layers.

Another described embodiment is a Recurrent Neural Network having recurrent layers. Each recurrent layer comprises combinations of, for instance, one or more of Gated Recurrent Units (GRU); LSTM units; linear combination layers; drop-out layers; and/or convolution layers.

Network Architecture Example 1: Fully-Connected Neural Network

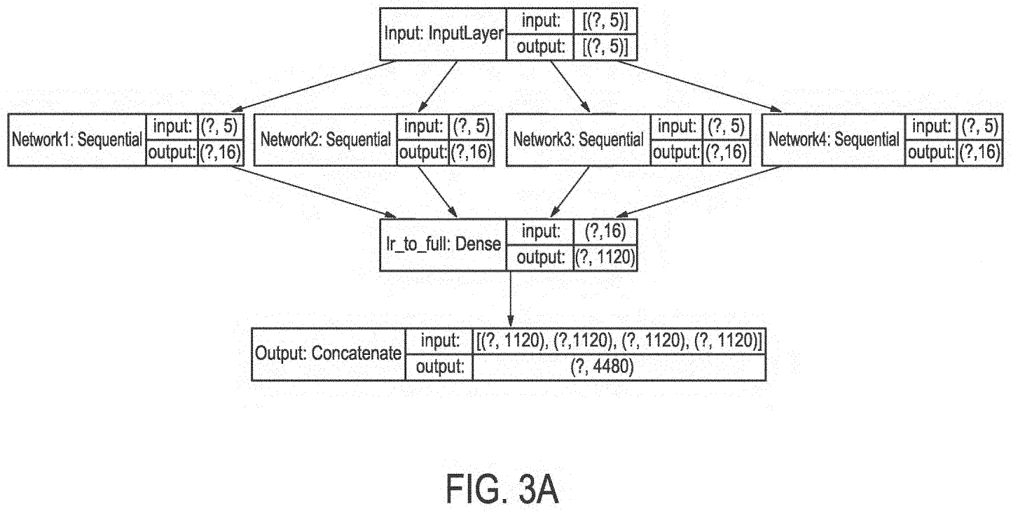

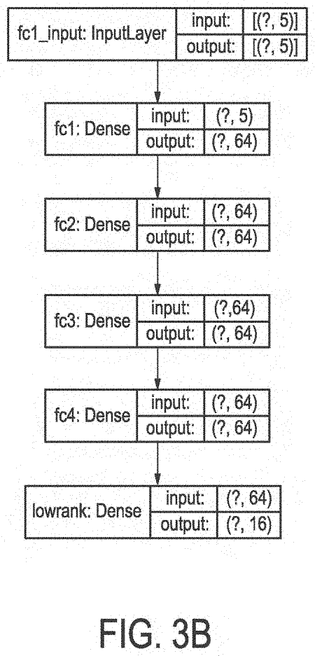

A fully-connected multi-layer neural network is the preferred implementation of the NN architecture of FIG. 2. FIG. 3A shows an example architecture, and the detailed structure of Networks 1-4 in FIG. 3A is shown in FIG. 3B. In FIG. 3A, inputs are T₁, T₂, B₁, TE and TR, and outputs are the MR signal and their derivatives for a fixed sequence length. In FIG. 3A, the sequence length is 1120. In FIG. 3B, “fc1” stands for fully-connected layer number 1. In an analogue manner, fc2 stands for fully-connected layer number 2, fc3 stands for fully-connected layer number 3, etc.

The layers included in Network 1-4 are shown in FIG. 3B. The input layer is connected to Network 1-4, and the outputs of Network 1-4 are connected to the “lr_to_full” layer, which is a fully-connected linear layer. The output of “lr_to_full” layer is then used as the input of the “Concatenate” layer, in order to obtain the data of preferred format.

The “?” signs indicate the batch size, which equals the number of voxels computed. For example, if we need to computed the signal for 1000 voxels, then “?” will be 1000. If signals and derivatives for 10000 voxels are to be computed, then: ?=10000.

Network Architecture Example 2: Recurrent Neural Network

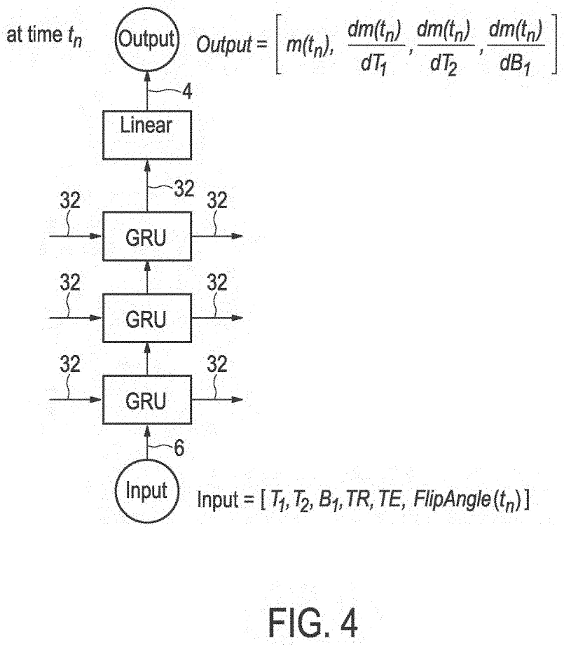

In accordance with another example, that is a multi-layer recurrent neural network (RNN) shown in FIG. 4, an additional optional input, i.e. the time-dependent FlipAngle(tₙ), is included. This network works for various sequence lengths. This network is more flexible than the previously described Fully-connected Neural Network since the sequence of time-dependent Flip angles need not to be known at the moment of the trainings step. In other words, a user could change the time dependent flip angles and still continue using the same neural network for reconstructions, without needing to re-train the network.

FIG. 4 shows the architecture for one layer of the RNN. FIG. 4 shows in addition the recurrent neural network with 3-layer Gated-Recurrent Unit (GRU) units. The horizontal three inputs and outputs of size 32 denote the state variable. The output at the top is the desired signal.

Alternative Methods for Calculating Y(αᵢ) and its Derivatives w.r.t. the Inputs α

A first alternative method to calculate Y(αᵢ) and its derivatives w.r.t. the inputs α is to use a Bloch equation simulator, which is a common way to compute the signal. When using the factorized model of the present application, the signal computed would be the product of U and Y(α) operators analogue to the neural network model. This reduces the to solve numerically the physical model represented by the Bloch equation.

Another alternative method to calculate Y(αᵢ) and its derivatives w.r.t. the inputs α is to use a dictionary based method. The signal is computed on a limited number of representative values to generate a database of signal waveforms (dictionary). From this dictionary the compression matrix U can be derived by for instance Singular Value Decomposition and the Y values from interpolation.

One example implementation of the dictionary-based method is as follows.

1. For a fixed MR scanning sequence, a dictionary D_{Full} is simulated by solving the Bloch equations (physical model) while varying the input parameters such as, for instance, T₁, T₂ and B₁. For T₁, many (for instance 100 or more) values in the range of 100 to 5000 ms are sampled. Usually, uniform sampling in a logarithmic scale is done. For T₂, many (for instance 100 or more) values in the range of 10 to 2000 ms are sampled. Usually, uniform sampling in a logarithmic scale is done. For B₁, a uniform sample of many (for instance 11 or more) values in the range of 0.8 to 1.2 T can be taken. The output dictionary value D_{Full} can be obtained by solving the Bloch equation for each combination of the above parameters; in this example, D_{F} would be a matrix of size 1120×(100*100*11), where 1120 is the MR sequence length, and each column of the matrix is the MR signal for specific values of T₁, T₂, and B₁.

2. The low-rank matrix U (compression matrix) is then computed from D_{full} by singular value decomposition (SVD) such that D_{full}=UY(α). For more info, see also McGivney, Debra F., et al. “SVD compression for magnetic resonance fingerprinting in the time domain.” IEEE transactions on medical imaging 33.12 (2014): 2311-2322.

3. In the factorized model, the Y(α₁) matrix is computed from the dictionary for any input value a by doing a multi-dimensional (3 dimension for T1, T2, and B1 respectively) interpolation from the compressed Dictionary matrix.

Therefore, although the NN is found to be a fast way to compute the magnetizations at echo time, the above provide alternative ways for calculating/obtaining the values for Y(α₁) and its derivatives w.r.t. the inputs α.

Example Reconstruction Data

Both balanced and gradient spoiled MR-STAT sequence are used with Cartesian acquisition and slowly or smoothly time-varying flip angle trains. In an embodiment, the applied pulse sequence is configured to yield varying flip angles. Preferably, the radio frequency excitation pattern of the applied pulse sequence is configured to yield smoothly varying flip angles, such that a corresponding point-spread function is spatially limited in a width direction. Smoothly varying may indicate a sequence wherein the amplitude of the RF excitations changes in time by a limited amount. The amount of change between two consecutive RF excitations during sampling of a k-space (or of each k-space) is smaller than a predetermined amount, preferably smaller than 5 degrees. Such acquisitions are done e.g. van der Heide, Oscar, et al. arXiv preprint arXiv:1904.13244 (2019), which is incorporated herein by reference in its entirety.

The neural networks are trained for balanced and spoiled signal models where the inputs are (T1, T2, B1, B0, TR, TE) and (T1, T2, B1, TR, TE), respectively. This can be done for instance as described in Weigel, Matthias. Journal of Magnetic Resonance Imaging 41.2 (2015): 266-295, which is incorporated herein by reference in its entirety. Imperfect slice profile is also modelled. Training of the NN is performed with Tensorflow using the ADAM optimizer, 6000 epochs. The NN surrogate results are obtained by both simulation results and measured data from a Philips Ingenia 1.5T scanner. It is noted that, generally, the predictive models disclosed herein, in particular the neural networks, are configured such that they can be trained independent of the sample or scanner. Once the model is trained with certain types of input parameters, the model is able to output results for such parameters.

The accelerated MR-STAT reconstruction algorithm incorporating the surrogate model and the above described alternating minimization scheme (in particular ADMM) is implemented in MATLAB on an 8-Core desktop PC (3.7 GHz CPU). To validate the reconstruction results, gel phantom tubes were scanned with a spoiled MR-STAT sequence on a Philips Ingenia 3T scanner, and an interleaved inversion-recovery and multi spin-echo sequence (2DMix, 7 minutes acquisition) provided by the MR vendor (Philips) was also scanned as a benchmark comparison.

For in-vivo validation, the standard and accelerated MR-STAT reconstructions are run on both gradient spoiled acquisition (using a scan time of 9.8 s, TR of 8.7 ms, and TE of 4.6 ms) and balanced acquisition (using a scan time of 10.3 s, TR of 9.16 ms, TE of 4.58 ms).

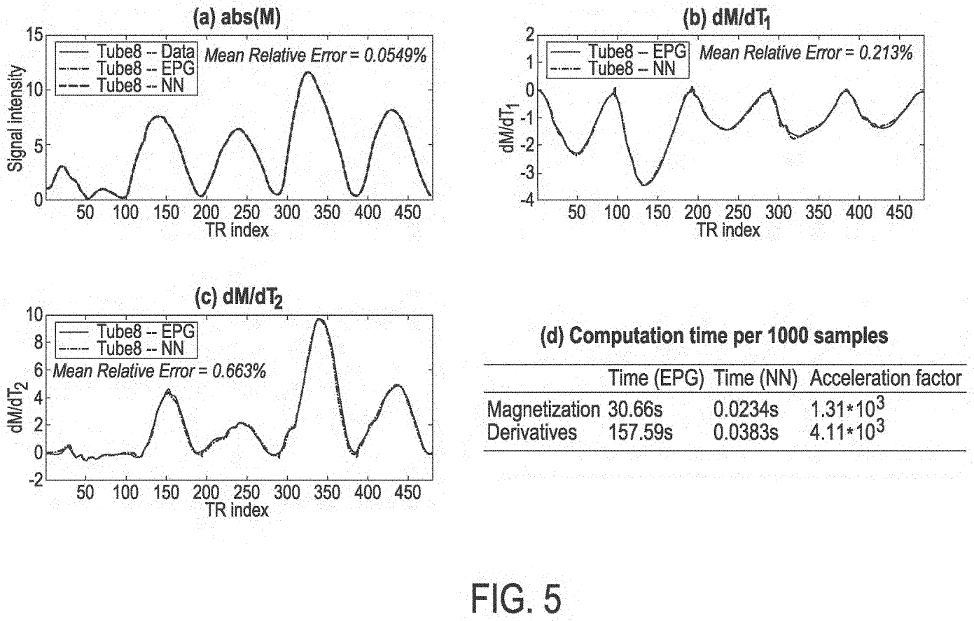

FIG. 5 summarizes the results of the reconstructions, showing that the combination of the NN surrogate model with the ADMM splitting scheme achieves an acceleration factor of about one thousand with negligible errors. FIG. 5 shows in addition high agreements in T₁ and T₂ maps obtained from standard MR-STAT reconstruction, accelerated MR-STAT reconstruction and a 2DMix acquisition for the gel phantom data. The lines overlap almost perfectly, indicating the negligible difference between the related art methods and the methods of the present application.

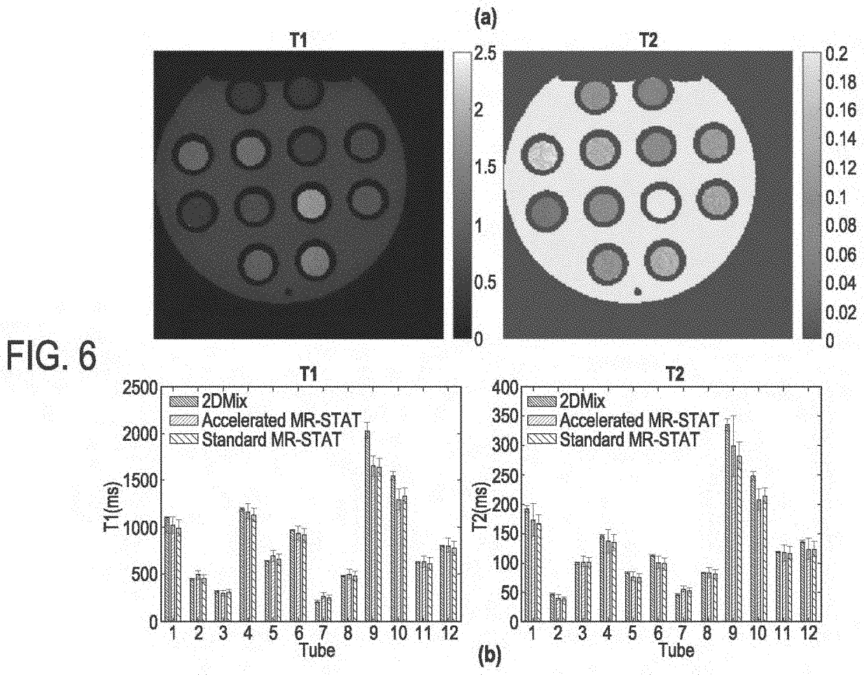

FIG. 6 shows the imaging results using the surrogate NN model of 12 gel tubes with different T₁ and T₂ values. The gel tubes were scanned using a spoiled sequence, and time-dependent signal and derivatives from one tube (T₁=612 ms, T₂=125 ms) are shown. The other 2 tubes show similar results. FIG. 6(a) shows T₁ and T₂ maps from accelerated MR-STAT reconstruction. In FIG. 6(b), bar plots of mean and standard T₁ and T₂ values for the twelve tube phantoms from both standard and accelerated MR-STAT reconstructions are shown. In addition, 2DMix results are included for reference. FIG. 6(b) in summary shows high agreements in T_{I} and T₂ maps obtained from standard MR-STAT reconstruction, accelerated MR-STAT reconstruction and a 2DMix acquisition for the gel phantom data.

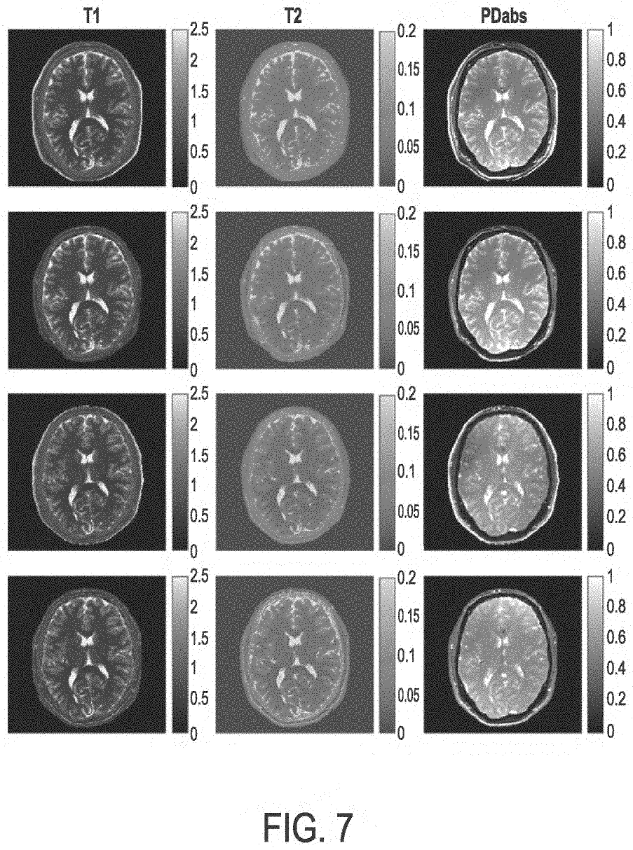

FIG. 7 shows in-vivo results of one representative slice from a healthy human brain; both standard and accelerated MR-STAT algorithms obtain similar quantitative maps from both balanced and gradient spoiled acquisitions. Quantitative maps including T₁, T₂ and PD from both balanced (scan time 10.3 s) and gradient spoiled (scan time 9.8 s) sequences are shown. The image size is 224×224 with resolution of 1.0×1.0×3.0 mm³. Four SVD compressed virtual-coil data are used for reconstruction.

In FIG. 7 are shown, from the top to bottom row: 1) data acquired with a gradient balanced sequence an reconstructed with standard MR-STAT algorithm; 2) data acquired with a gradient balanced sequence an reconstructed with the presently disclosed accelerated MR-STAT algorithm; 3) data acquired with a gradient spoiled sequence an reconstructed with a standard MR-STAT algorithm (e.g. as per WO 2016/184779 A1); and 4) data acquired with a gradient spoiled sequence an reconstructed with the presently disclosed accelerated MR-STAT algorithm.

With the accelerated MR-STAT algorithm, one 2D slice reconstruction requires approximately 157 seconds with single-coil data, and 671 seconds with four compressed virtual coil data. Compared with the results reported previously (50 minutes single-coil reconstruction on a 64 CPU's cluster as per e.g. van der Heide, Oscar, et al. in Proceedings of the ISMRM, Montreal, Canada, program number 4538 (2019)). The present accelerated method thus obtains a two order of magnitude acceleration in reconstruction time.

Now referring to FIG. 6, the device 700, which is an embodiment of the device for determining a spatial distribution of at least one tissue parameter within a sample based on a time domain magnetic resonance, TDMR, signal emitted from the sample after excitation of the sample according to an applied pulse sequence, comprises a processor 710 which is configured to perform any one or more of the methods described above. The device 700 may comprise a storage medium 720 for storing any of the model, parameters, and/or other data required to perform the method steps. The storage medium 720 may also store executable code that, when executed by the processor 710, executes one or more of the method steps as described above. The device 700 may also comprise a network interface 730 and/or an input/output interface 740 for receiving user input. Although shown as a single device, the device 700 may also be implemented as a network of devices such as a system for parallel computing or a supercomputer or the like.

A person of skill in the art would readily recognize that steps of various above-described methods can be performed by programmed computers. Herein, some embodiments are also intended to cover program storage devices, e.g., digital data storage media, which are machine or computer readable and encode machine-executable or computer-executable programs of instructions, wherein said instructions perform some or all of the steps of said above-described methods. The program storage devices may be, e.g., digital memories, magnetic storage media such as a magnetic disks and magnetic tapes, hard drives, or optically readable digital data storage media. The embodiments are also intended to cover computers programmed to perform said steps of the above-described methods.

The functions of the various elements shown in the FIGS., including any functional blocks labelled as “units”, “processors” or “modules”, may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “unit”, “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read only memory (ROM) for storing software, random access memory (RAM), and non volatile storage. Other hardware, conventional and/or custom, may also be included. Similarly, any switches shown in the FIGS. are conceptual only. Their function may be carried out through the operation of program logic, through dedicated logic, through the interaction of program control and dedicated logic, or even manually, the particular technique being selectable by the implementer as more specifically understood from the context.

It should be appreciated by those skilled in the art that any block diagrams herein represent conceptual views of illustrative circuitry embodying the principles of the invention. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

Whilst the principles of the described methods and devices have been set out above in connection with specific embodiments, it is to be understood that this description is merely made by way of example and not as a limitation of the scope of protection which is determined by the appended claims.

What is claimed is:

1. A method for determining a spatial distribution of at least one tissue parameter within a sample based on a measured time domain magnetic resonance, TDMR, signal emitted from the sample after excitation of the sample according to an applied pulse sequence, the method comprising:
i) determining a TDMR signal model to approximate the emitted time domain magnetic resonance signal, wherein the TDMR signal model is dependent on TDMR signal model parameters comprising the at least one tissue parameter within the sample,
wherein the model is factorized into one or more first matrix operators that have a non-linear dependence on the at least one tissue parameter and a remainder of the TDMR signal model;
ii) performing optimization with an objective function and constraints based on the first matrix operators and the remainder of the TDMR signal model until a difference between the TDMR signal model and the TDMR signal emitted from the sample is below a predefined threshold or until a predetermined number of repetitions is completed, in order to obtain an optimized or final set of TDMR signal model parameters; and
iii) obtaining from the optimized or final set of TDMR signal model parameters the spatial distribution of the at least one tissue parameter.

2. The method according to claim 1, wherein one of the one or more first matrix operators represents the TDMR signal at echo time.

3. The method according to claim 2, wherein the model is factorized into at least two first matrix operators that have a non-linear dependence on the at least one tissue parameter and the remainder of the TDMR signal model, wherein a first of the at least two first matrix operators represents the TDMR signal at echo time, and wherein a second of the at least two first matrix operators represents a readout encoding matrix operator of the TDMR signal.

4. The method according to claim 1, wherein the remainder of the TDMR signal model comprises a readout encoding matrix operator of the TDMR signal.

5. The method according to claim 1, wherein the performing the optimization comprises using a surrogate predictive model wherein a TDMR signal is computed at echo time only based on the one or more first matrix operators, wherein the surrogate predictive model outputs the TDMR signal at echo time and one or more TDMR signal derivatives at echo time with respect to each of the at least one tissue parameter within the sample.

6. The method according to claim 1, wherein the TDMR signal model is a volumetric signal model and comprises a plurality of voxels, wherein preferably the step of performing optimization is done iteratively for each line in a phase encoding direction of the voxels of the TDMR signal model.

7. The method according to claim 6, wherein the TDMR signal at echo time is a compressed TDMR signal at echo time for each line of voxels, wherein the TDMR signal at echo time is compressed for each voxel, and/or
wherein the remainder of the TDMR signal model is factorized into a diagonal phase encoding matrix, preferably for each of the lines of voxels, and a compression matrix for the TDMR signal at echo time.

8. The method according to claim 7, wherein the optimization with an objective function and constraints is representable by:
$${min}_{α} \frac{1}{2} {‖ D - {\sum }_{i = 1}^{{N}_{y}} {C}_{i}^{p} UY ( {α}_{i} ) {C}^{r} ( {α}_{i} ) ‖}_{F}^{2} \qquad ( Eq . 1 )$$
wherein;
αᵢ denotes the at least one tissue parameter for the ith line of voxels in the phase encoding direction;
Cᵢ^{p}∈ [symbol] ^{N}^{_{Tr}}^{×N}^{_{Tr}} is the diagonal phase encoding matrix for the ith line of voxels in the phase encoding direction;
U∈ [symbol] ^{N}^{_{Tr}}^{×N}^{_{Eig}} is the compression matrix for the TDMR signal at echo time, N_{Tr} being a number of RF pulses and N_{Eig} being a length of the compressed TDMR signal at echo time;
Y(αᵢ)∈ [symbol] ^{N}^{_{Eig}}^{×N}^{ₓ} is the compressed echo time TDMR signal for the ith line in the phase encoding direction of voxels, wherein each column of Y(αᵢ) is the compressed TDMR signal for one voxel in the ith line;
C^{r}(αᵢ)∈ [symbol] ^{N}^{_{Tr}}^{×N}^{_{Read}} is the readout encoding matrix for the ith line in the phase encoding direction of voxels;
D∈ [symbol] ^{N}^{ₓ}^{×N}^{_{Read}} is the TDMR signal emitted from the sample in a matrix format, N_{Read} being a number of readout points every TR;
N_{y} represents the number of voxels or rows of voxels in the phase encoding direction.

9. The method according to claim 1, wherein the optimization with an objective function and constraints is representable by:
$${min}_{α , Z , W} {ℒ}_{λ} ( α , Z , W ) \qquad ( Eq . 2 )$$
wherein; [symbol]
_{A} is a Lagrangian with λ representing the Lagrange multiplier;
α represents the at least one tissue parameter;
Z represents an alternative or slack variable; and
W represents a dual variable for Z.

10. The method according to claim 9, wherein the non-linear optimization problem is represented by:
$${min}_{α , Z , W} {ℒ}_{λ} ( α , Z , W ) \qquad ( Eq . 3 )$$
$$= {min}_{α , Z , W} \frac{1}{2} {‖ D - {\sum }_{i = 1}^{{N}_{y}} {C}_{i}^{p} {UZ}_{i} ‖}_{F}^{2} + \frac{λ}{2} {\sum }_{i = 1}^{{N}_{y}} {‖ Y ( {α}_{i} ) {C}^{r} ( {α}_{i} ) - {Z}_{i} + {W}_{i} ‖}_{F}^{2} - \frac{λ}{2} {\sum }_{i = 1}^{{N}_{y}} {‖ {W}_{i} ‖}_{F}^{2}$$
wherein;
Wᵢ∈ [symbol] ^{N}^{_{Eig}}^{×N}^{_{Read}} represents a dual variable for Zᵢ;
αᵢ denotes the at least one tissue parameter for the ith line of voxels in the phase encoding direction;
cᵢ^{p}∈ [symbol] ^{N}^{_{Tr}}^{×N}^{_{Tr}} is the diagonal phase encoding matrix for the ith line of voxels in the phase encoding direction;
U∈ [symbol] ^{N}^{_{Tr}}^{×N}^{_{Eig}} is the compression matrix for the TDMR signal at echo time, N_{Tr} being a number of RF pulses and N_{Eig} being a length of the compressed TDMR signal at echo time;
Y(αᵢ)∈ [symbol] ^{N}^{_{Eig}}^{×N}^{ₓ} is the compressed echo time TDMR signal for the ith line in the phase encoding direction of voxels, wherein each column of Y(αᵢ) is the compressed TDMR signal for one voxel in the ith line;
C^{r}(αᵢ)∈ [symbol] ^{N}^{ₓ}^{×N}^{_{Read}} is the readout encoding matrix for the ith line in the phase encoding direction of voxels;
D∈ [symbol] ^{N}^{_{Tr}}^{×N}^{_{Read}} is the TDMR signal emitted from the sample in a matrix format, N_{Read} being a number of readout points every TR;
N_{y} represents the number of voxels or rows of voxels in the phase encoding direction.

11. The method according to claim 9, wherein the step ii) of performing optimization comprises:
using a set of equations based on the factorized model, each equation of the set of equations being arranged to obtain an updated respective variable, wherein the variables comprise a first variable representing an auxiliary or slack variable, a second variable representing the at least one tissue parameter and a third variable representing a dual variable, the minimizing comprising;
iii) obtaining an update value for the first variable while keeping the other variables fixed;
iv) then obtaining an update for the second variable while keeping the other variables fixed;
v) then obtaining an update for the third variable while keeping the other variables fixed, and
vi) repeating steps iii), iv), and v) until a difference between the TDMR signal model and the measured TDMR signal using the updated values of the respective variables as the respective input until a difference between the updated second variable and the input second variable is smaller than a predefined threshold or until a predetermined number of repetitions is completed, thereby obtaining a final updated set of TDMR signal model parameters,
wherein preferably:
each equation is configured to obtain an updated variable for a line of voxels in the phase encoding direction; and/or
the minimizing comprises estimating an initial set of the variables and thereafter sequentially performing the steps iii), iv) and v) according to;
iii) obtaining an updated value for the first variable using the estimated initial set of variables as input;
iv) obtaining an updated value for the second variable using the updated first variable and the initial third variable as input;
v) obtaining an updated value for the third variable using the updated first variable and the updated second variable as input, and
the step vi) of repeating is performed by using the updated values of the respective variables as the respective input until a difference between the updated second variable and the input second variable is smaller than a predefined threshold.

12. The method according to claim 11, wherein the step ii) of performing non-linear optimization comprises, for the (k+1)^{th} iteration:
obtaining the updated value for the first variable according to
$$\begin{matrix}{Z}^{( k + 1 )} = arg {min}_{Z} {ℒ}_{λ} ( {α}^{( k )} , Z , {W}^{( k )} ) ; \\ = {( {C}^{*} C + λ I )}^{( - 1 )} ( {C}^{*} D + λ {M}^{( k )} + λ {W}^{( k )} ) ,\end{matrix}$$
wherein I is an identity matrix,
wherein
$$C = [ {C}_{1}^{p} U , {C}_{2}^{p} U , … , {C}_{{N}_{y}}^{p} U ] ∈ {ℂ}^{{N}_{TR} \times ( {N}_{eig} * {N}_{y} )} , \\ and {M}^{( k )} = [ \begin{matrix}Y ( {α}_{1}^{( k )} ) {C}^{r} ( {α}_{1}^{( k )} ) \\ Y ( {α}_{2}^{( k )} ) {C}^{r} ( {α}_{2}^{( k )} ) \\ … \\ Y ( {α}_{{N}_{y}}^{( k )} ) {C}^{r} ( {α}_{{N}_{y}}^{( k )} )\end{matrix} ] ;$$
obtaining the updated value for the second variable according to
α^{(k+t)}=argmin_{α} [symbol] _{λ}(α,Z^{(k+1)},W^{(k)});
αᵢ^{(k+1)}=argmin_{α}_{ᵢ}∥Y(αᵢ)C^{r}(αᵢ)−Zᵢ^{(k+1)}+Wᵢ^{(k)}∥_{F}² for i∈[1,N_{y}]; and
obtaining the updated value for the third variable according to
Wᵢ^{(k+1)}=Wᵢ^{(k)}+Y(αᵢ^{(k+1)})C^{r}(αᵢ^{(k+1)})−Zᵢ^{(k+1)}.

13. The method according to claim 11, wherein the obtaining the updated value for the second variable is performed by solving N_{y} separate nonlinear problems using a trust-region method.

14. The method according to claim 1, wherein the step ii) of performing optimization comprises using Alternating Direction Method of Multipliers (ADMM).

15. The method according to claim 5, wherein the surrogate predictive model is implemented as a neural network, a Bloch equation based model or simulator, or a dictionary based model.

16. The method according to claim 15, wherein the neural network is implemented as a deep neural network or a recurrent neural network, wherein, when the neural network is implemented as the deep neural network, the deep neural network is preferably fully connected.

17. The method according to claim 1, wherein the at least one tissue parameter comprises any one of a T1 relaxation time, T2 relaxation time, T2* relaxation time and a proton density, or a combination thereof.

18. The method according to claim 1, wherein the TDMR signal model is a Bloch based volumetric signal model.

19. A device for determining a spatial distribution of at least one tissue parameter within a sample based on a time domain magnetic resonance, TDMR, signal emitted from the sample after excitation of the sample according to an applied pulse sequence, the device comprising a processor which is configured to:
i) determine a TDMR signal model to approximate the emitted time domain magnetic resonance signal, wherein the TDMR signal model is dependent on TDMR signal model parameters comprising the at least one tissue parameter within the sample,
wherein the model is factorized into one or more first matrix operators that have a non-linear dependence on the at least one tissue parameter and a remainder of the TDMR signal model;
ii) perform optimization with an objective function and constraints based on the first matrix operators and the remainder of the TDMR signal model until a difference between the TDMR signal model and the TDMR signal emitted from the sample is below a predefined threshold or until a predetermined number of repetitions is completed, in order to obtain an optimized or final set of TDMR signal model parameters; and
iii) obtain from the optimized or final set of TDMR signal model parameters the spatial distribution of the at least one tissue parameter.

20. A method of obtaining at least one magnetic resonance, MR, signal derivative with respect to at least one respective tissue parameter of an MR signal, the MR signal being emitted from a sample after excitation of the sample according to an applied pulse sequence, the method comprising;
performing an iterative non-linear optimization with an objective function and constraints in order to obtain an optimized or final value for the at least one MR signal derivative with respect to the at least one respective tissue parameter,
wherein the performing of the optimization comprises, for each iteration of the non-linear optimization, using a predictive model receiving the at least one tissue parameter as input and outputting the at least one MR signal derivative with respect to each of the at least one time dependent parameter within the sample.

21. The method according to claim 20, wherein the predictive model is implemented as a neural network configured to accept the at least one tissue parameter and parameters relating to the applied pulse sequence as input parameters, wherein the neural network is preferably a deep neural network or a recurrent neural network; and/or
wherein the predictive model is implemented as a dictionary based predictive model or a Bloch equation based model; and/or
wherein the predictive model is arranged to further predict or compute values of a magnetization and one or more derivatives thereof with respect to respective ones of the at least one tissue parameter within the sample, and/or
wherein the at least one tissue parameter comprises one or any combination of a T₁ relaxation time, a T₂ relaxation time, a T₂* relaxation time and a proton density, PD.

22. The method according to claim 20, wherein the predictive model is arranged to output the MR signal for echo time only; and/or
wherein the MR signal is a time domain magnetic resonance, TDMR, signal.

23. A computer program product comprising computer-executable instructions for performing the method of claim 1, when the program is run on a computer.

24. A computer program product comprising computer-executable instructions for performing the method of claim 20, when the program is run on a computer.
